(19) United States
(12) Patent Application Publication
(10) Pub. No.: US 2009/0001338 A1
(43) Pub. Date: Jan. 1, 2009

(54) Seek-and-scan probe memory devices with nanostructures for improved bit size and resistance contrast when reading and writing to phase-change media

(76) Inventors: Nathan Franklin, San Mateo, CA (US); Qing Ma, San Jose, CA (US); Valluri R. Rao, Saratoga, CA (US); Mike Brown, Phoeniz, AZ (US); Yang Jiao, Sunnyvale, CA (US)

Correspondence Address: SETH KALSON;c/o INTELLEVATE, LLC, P.O. BOX 52050, MINNEAPOLIS, MN, 55402, US

(21) Appl. No.: 11/824,382

(22) Filed: Jun. 29, 2007

(51) Int. Cl. H01L 47/00

(52) U.S. Cl. 257/2; 257/E47.001

(57) ABSTRACT

A seek-and-scan probe memory device comprising a patterned capping layer over a phase-change media, where the patterned capping layer defines the bit locations on the phase-change media. The patterned capping layer may be formed from self-assembled structures. In other embodiments, nanostructures are formed on the bottom electrode below the phase-change media to focus an applied electric field from the probe, so as to increase bit density and contrast. The nanostructures may be a regular or random array of nanostructures, formed by using a self-assembling material. The nanostructures may be conductive or non-conductive. Other embodiments are described and claimed.

### FIELD

The present invention relates to memory devices, and more particularly, to seek-and-scan probe memory devices with phase-change media.

### BACKGROUND

In a seek-and-scan probe memory device, a probe uses an electric field to write, read, or erase data stored in a phase-change media. Often, the phase-change media is coated with a protective coating (capping layer) that is usually weakly conductive. Consequently, when writing (storing) a bit, the conductive coating spreads out the applied electric field, so that the region in the media used to store the written bit is relatively large. This reduces storage density. Also, when reading a bit, the coating shunts current, thereby reducing “contrast”, e.g., the resolution at which a bit may be read is reduced.

### BRIEF DESCRIPTION OF THE DRAWINGS

FIGS. 1A-1F illustrate a process and memory device according to an embodiment of the present invention.

FIGS. 2A and 2B illustrate a memory device according to an embodiment of the present invention.

FIGS. 3A through 3E illustrate a process and memory device according to an embodiment of the present invention.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

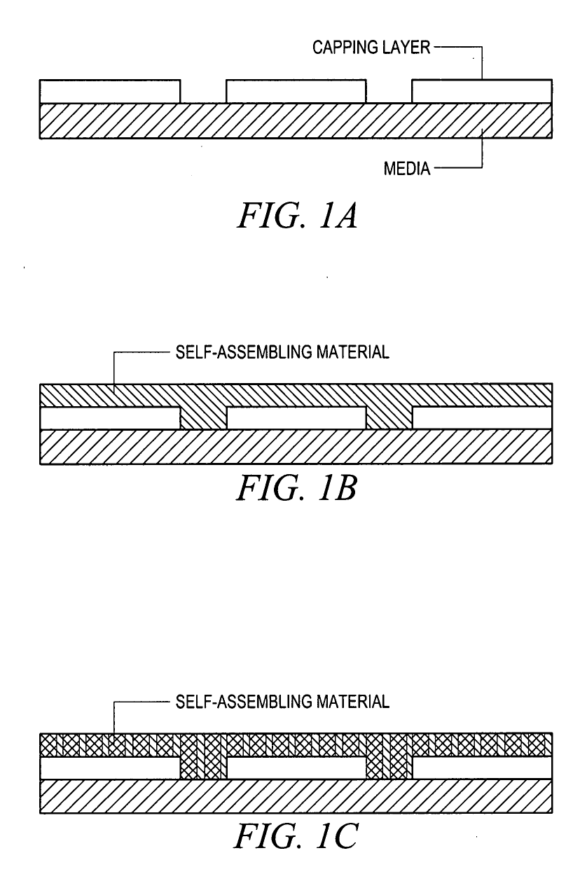

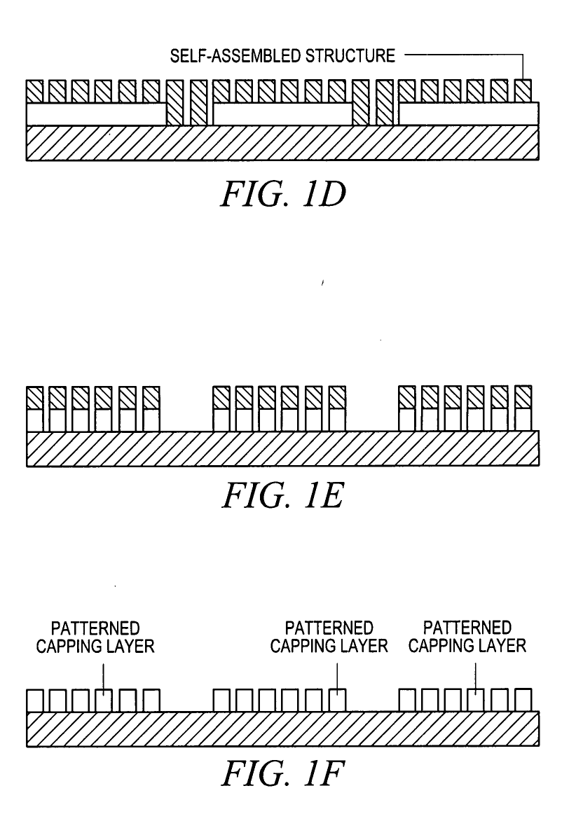

In some embodiments, a capping layer is processed to have regular island structures so that each island corresponds to a single bit. FIGS. 1A-F illustrate an example process. In FIG. 1A, a capping layer is patterned using conventional lithography to form templates that will be used to induce a regular self-assembling pattern. In FIG. 1B, a self-assembling material, such as a suitable co-polymer, is applied. In FIG. 1C, heat or light exposure is applied to induce a self assembling process. In FIG. 1D, reactive ion etching is applied, selectively to the co-polymer material, to form structures of the self-assembling material as indicated. For some embodiments, the reactive ion etching may not be needed if such structures automatically form. In FIG. 1E, reactive ion etching is applied selectively to the capping layer pattern as indicated. In FIG. 1E the self-assembled structures are stripped away to reveal the patterned capping layer.

For simplicity, not all components of a memory device are illustrated in FIGS. 1A-F. For example, a conductor may be present below the media in FIGS. 1A-F.

In some embodiments, a regular array of nanostructures is patterned on the bottom electrode (conductive layer) below the phase-change media, where each nanostructure corresponds to a single memory bit. The nanostructures have a focusing effect on the applied electric field from the probe, which mitigates spreading of the applied electric field so that the resulting bit is smaller and the reading contrast is higher.

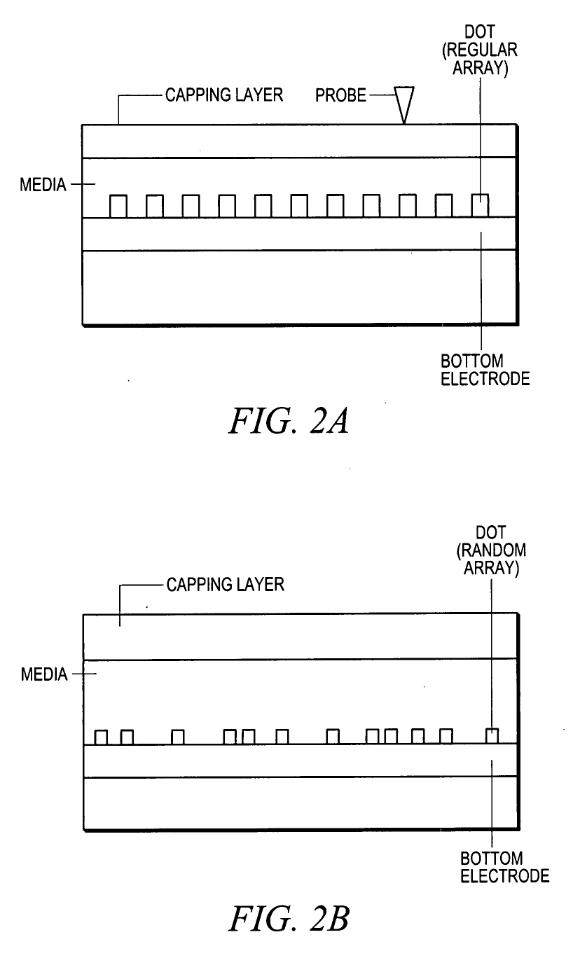

An embodiment is illustrated in FIG. 2A, showing a regular array of nanostructures formed on the bottom electrode. The processing steps for forming the regular array of nanostructures may be similar to that described with respect to FIGS. 1A-F.

In other embodiments, the nanostructures may be formed on the bottom electrode arranged as an irregular, or random, array. An example embodiment is illustrated in FIG. 2B, showing a random array of nanostructures formed on the bottom electrode. The type of focusing effect depends upon whether the nanostructures are conductive, or a dielectric (non-conductive). When conductive, an electric field tends to concentrate at sharp or rounded edges, in which case the applied electric field is focused from the probe, through the media, to the nanostructure. When a dielectric, the electric field is guided away from the nanostructures, toward the space between the nanostructures.

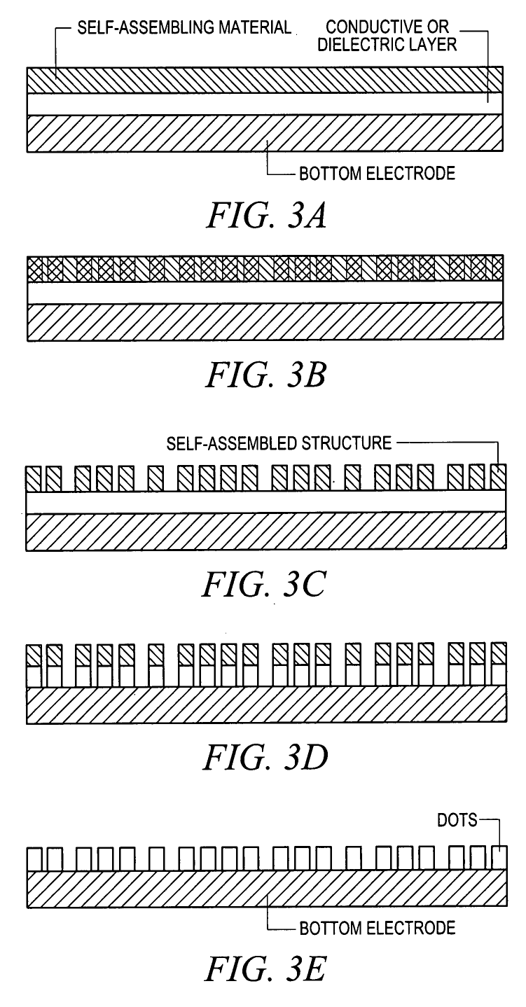

The processing steps for forming the random array of nanostructures may be similar to that described with respect to FIGS. 1A-F. An example embodiment is illustrated in FIGS. 3A-E. In FIG. 3A, a self-assembling material, such as a co-polymer, is applied to a conductive or dielectric layer, which will later be the random array of nanostructures. In FIG. 3B, heat or light exposure is applied to induce a self-assembling process. In FIG. 3C, reactive ion etching is utilized to form the self-assembled structures, but may not be needed it the self-assembled structures form automatically. In FIG. 3D, reactive ion etching is applied to remove portions of the conductive or dielectric layer not underneath one of the self-assembled structures. In FIG. 3E, the self-assembled structures are stripped away to reveal the random array of nanostructures.

In the above description, the term capping layer is not mean to imply that there are no other layers above the capping layer. In practice, there may be additional layers.

The phase-change media may be, for example, a chalcogenide material that can exist in two phases, amorphous and crystalline. The amorphous phase is non-conductive, whereas the crystalline phase is conductive.

Various modifications may be made to the disclosed embodiments without departing from the scope of the invention as claimed below.

What is claimed is:

1. A memory device comprising:
a phase-change media comprising bit regions; and
a patterned layer formed on the phase-change media, the patterned layer comprising self-assembled structures to focus an applied electric field onto the bit regions.

2. The memory device as set forth in claim 1, the phase-change media comprising a chalcogenide material having an amorphous phase and a crystalline phase, where the amorphous phase is non-conductive and the crystalline phase is conductive.

3. The memory device as set forth in claim 1, wherein the self-assembled structures comprise a non-conductive dielectric material.

4. A memory device comprising:
a bottom electrode;
an array of nanostructures formed on the electrode;
a phase-change media formed on the array of nanostructures; and
a layer formed on the phase-change media.

5. The memory device as set forth in claim 4, wherein the array of nanostructures is regular.

6. The memory device as set forth in claim 4, wherein the array of nanostructures is a random array.

7. The memory device as set forth in claim 4, wherein each nanostructure is conductive.

8. The memory device as set forth in claim 7, wherein the array of nanostructures is regular.

9. The memory device as set forth in claim 7, wherein the array of nanostructures is random.

10. The memory device as set forth in claim 4, wherein each nanostructure is non-conductive.

11. The memory device as set forth in claim 10, wherein the array of nanostructures is regular.

12. The memory device as set forth in claim 10, wherein the array of nanostructures is random.

13. The memory device as set forth in claim 4, wherein the array of nanostructures comprises self-assembled structures.
